(19) United States
(12) Patent Application Publication
(10) Pub. No.: US 2002/0196034 A1
(43) Pub. Date: Dec. 26, 2002

(54) Object recognition method for intelligent cruise control system of vehicle

(76) Inventor: Jee-Young Kim, Kyungki-do (KR)

Correspondence Address: Pennie & Edmonds, LLP, 3300 Hillview Avenue, Palo Alto, CA, 94304, US

(21) Appl. No.: 10/105,726

(22) Filed: Mar. 20, 2002

(30) Foreign Application Priority Data
Jun. 20, 2001 (KR) 2001-35143

(51) Int. Cl. G01R 27/32; G01R 27/04

(52) U.S. Cl. 324/635

(57) ABSTRACT

An object recognition method for an intelligent cruise control system of a vehicle with an electronic control unit for performing cruise control and two sensors in communication with the electronic control unit for sensing distance between the vehicle and at least one forward object is provided, which includes: determining a shape of a lane marker; detecting distances from the two sensors to a forward object, and determining a shape of the forward object using the distances; determining whether the shape of the lane marker coincides with the shape of the forward object; and determining that the forward object is a stationary object if it is determined that the shape of the lane marker coincides with the shape of the forward object.

### FIELD OF THE INVENTION

The present invention relates to a control method for a vehicle safety system, and more particularly, to an object recognition method for an intelligent cruise control system able to cruise a vehicle using various sensors.

### BACKGROUND OF THE INVENTION

Generally, an intelligent cruise control (hereinafter referred to as an ICC) system is a representative technique for an advanced safety vehicle, the ICC system controlling an engine, a transmission, a brake system, a steering system, and various sensors and actuators such that a vehicle accident can be prevented and injury to a driver and passengers caused by a vehicle accident can be minimized.

The ICC system controls a throttle valve and a brake by detecting distance to an obstacle and a relative speed between the vehicle and a foregoing vehicle, and using vehicle driving information such as a vehicle speed and a desired vehicle speed such that a suitable distance between the vehicles is maintained.

In the ICC system, a distance between the vehicles is measured by a laser radar or a MMW (millimeter wave) radar sensor mounted in the forward part of a vehicle, and acceleration or deceleration of a vehicle is determined according to the distance between the vehicles and whether there is a foregoing vehicle.

However, distance data of the radar sensor may have error data owing to existence of stationary objects such as a line of trees, a guardrail, or a roadside berm.

Although these error data can generally be overcome by calculation of a relative speed, it is difficult to recognize stationary objects only by the data of the radar sensor on a severely curved road because the relative speed is calculated while the vehicle is turning.

### SUMMARY OF THE INVENTION

The present invention provides an object recognition method for the ICC system of a vehicle in which the object is accurately recognized by eliminating errors of distance data on a curved road. A preferred embodiment of the present invention includes determining a shape of a lane marker, detecting distances from two sensors to a forward object, and determining a shape of the forward object using the distances, determining whether the shape of the lane marker coincides with the shape of the forward object, and determining that the forward object is a stationary object if it is determined that the shape of the lane marker coincides with the shape of the forward object.

In one alternative embodiment of the present invention, the shape of the lane marker is determined using an imaginary curve that represents a shape of a line of travel of the vehicle that is found by evaluating both a line extending from a front wheel and a line extending from a rear wheel.

In another alternative embodiment of the present invention, the two sensors are radar sensors.

### BRIEF DESCRIPTION OF THE DRAWINGS

The accompanying drawings, which are incorporated in and constitute a part of the specification, illustrate an embodiment of the invention, and, together with the description, serve to explain the principles of the invention, where:

FIG. 1 schematically shows a method for recognizing an object according to the present invention; and

FIG. 2 is a flowchart showing the object recognition method according to the present invention.

### DETAILED DESCRIPTION OF THE PREFERRED EMBODIMENTS

Hereinafter, a preferred embodiment of the present invention will be described in detail with reference to the accompanying drawings.

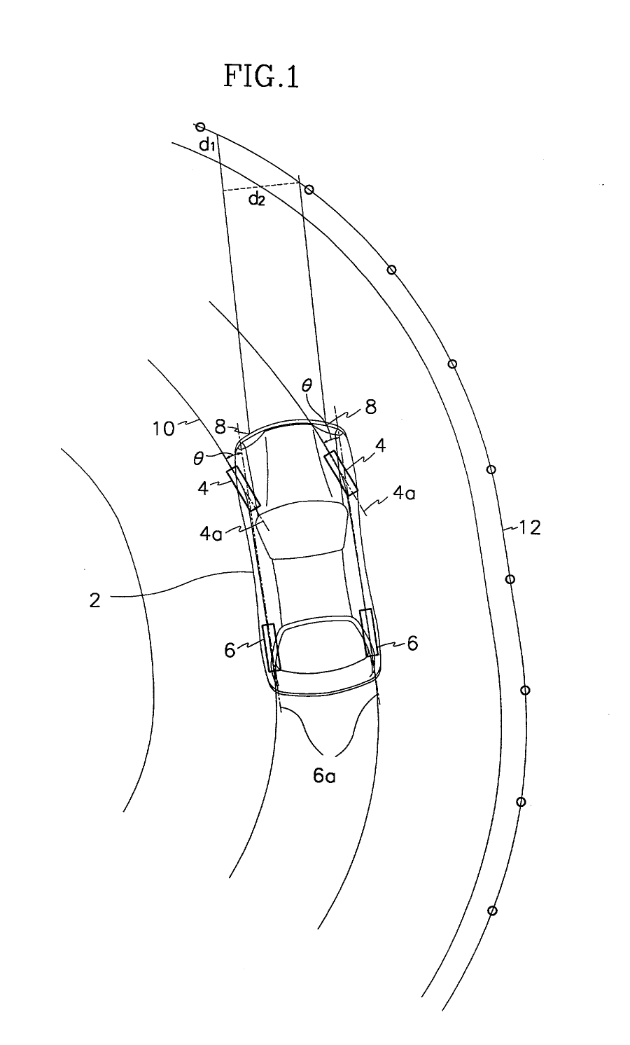

Referring to FIG. 1, two radar sensors 8 are provided in a front of a vehicle 2. Preferably, the radar sensors are respectively located on an extension line of a rear wheel 6 and a front wheel 4.

The radar sensors 8 are connected to an ICC controller, and data sensed by the radar sensors 8 are input to the ICC controller. The ICC controller controls the vehicle to overcome dangerous situations by controlling a steering angle, a throttle valve, or a brake after the following process.

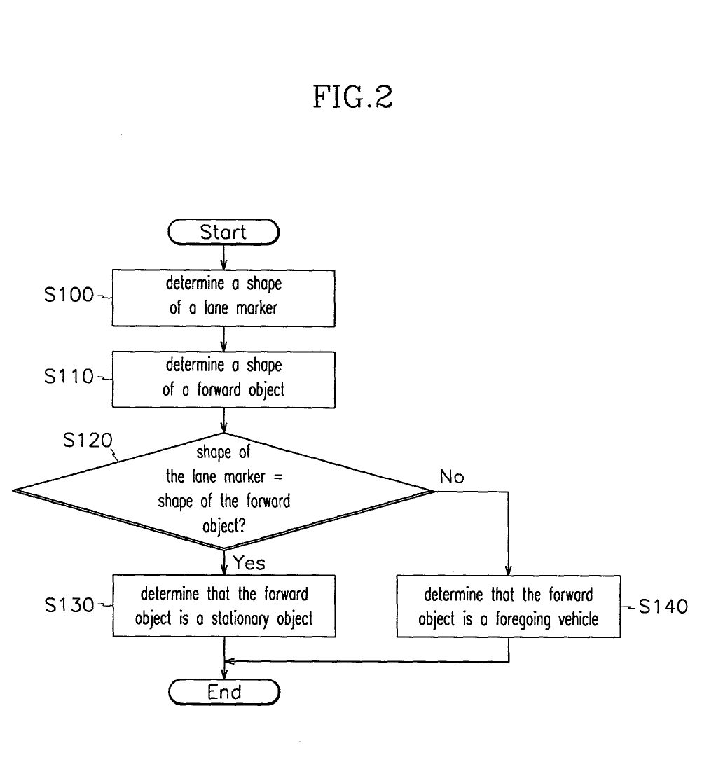

As shown in FIG. 2, a shape of a lane marker beside which the vehicle is running is determined in step S100, from an imaginary curve 10 that represents a shape of a line of travel of the vehicle which is found by evaluating extension lines 4a and 6a of the front wheel 4 and the rear wheel 6, respectively.

That is, by calculating the angle θ of the front wheel using a steering angle sensor and acquiring the imaginary curve 10 from the respective extension lines 4a and 6a of the front wheel 4 and the rear wheel 6, the shape of the lane marker can be acquired. The extension line 6a of the rear wheel 6 always coincides with the direction the vehicle is pointed.

The shape of a forward object is determined using the information of the radar sensor 8 in step S110 as follows. If a difference d1 between two distances from the two radar sensors to the forward object is acquired, the shape of the object is acquired through simple geometric calculations considering the difference dl and a distance d2 between the two sensors.

Then, it is determined if the shape of the lane marker coincides with the shape of the object (S120). If it is determined that the shape of the lane marker coincides with the shape of the object, the object is determined to be a stationary object 12 such as a guardrail, a line of trees, etc, and the object is then disregarded (S130). However, if it is determined that the shape of the lane marker does not coincide with the shape of the object, it is determined that the object is a foregoing vehicle (S140), and therefore the throttle valve and the brake are operated for securing vehicle safety.

As stated above, the object recognition method according to the present invention decreases errors in distance data caused by stationary objects when the vehicle is running on a curved road.

Also, the method for recognizing the curve angle can be applied to lateral control of a vehicle for warning and preventing lane deviation.

What is claimed is:

1. An object recognition method for an intelligent cruise control system of a vehicle with an electronic control unit for performing cruise control and two sensors in communication with the electronic control unit for sensing distance between the vehicle and at least one forward object, the method comprising:
determining a shape of a lane marker;
detecting distances from the two sensors to a forward object, and determining a shape of the forward object using the distances;
determining whether the shape of the lane marker is identical to the shape of the forward object; and
determining that the forward object is a stationary object if it is determined that the shape of the lane marker coincides with the shape of the forward object.

2. The method of claim 1, further comprising
determining that the forward object is a foregoing vehicle if it is determined that the shape of the lane marker does not coincide with the shape of the forward object.

3. The method of claim 1, wherein the shape of the lane marker is determined using an imaginary curve that represents a shape of a line of travel of the vehicle that is found by evaluating both a line extending from a front wheel and a line extending from a rear wheel.

4. The method of claim 1, wherein the shape of the forward object is determined using a difference between two distances from the two sensors to the forward object and a distance between two sensors.

5. The method of claim 1, wherein the two sensors are radar sensors.
